(19) United States
(12) Patent Application Publication
(10) Pub. No.: US 2026/0287614 A1
(43) Pub. Date: Sep. 24, 2026

(54) A PROBE HEAD FOR THE TESTING OF ELECTRONIC DEVICES HAVING CONTACT PROBES WITH IMPROVED ELASTIC PROPERTIES

(71) Applicant: TECHNOPROBE S.P.A., Cernusco Lombardone (LC) (IT)

(72) Inventors: Giuseppe CRIPPA, Cernusco Lombardone (LC) (IT); Roberto CRIPPA, Cernusco Lombardone (LC) (IT); Stefano FELICI, Cernusco Lombardone (LC) (IT); Nadia PADERNO, Cernusco Lombardone (LC) (IT)

(73) Assignee: TECHNOPROBE S.P.A., Cernusco Lombardone (LC) (IT)

(21) Appl. No.: 19/473,917

(22) PCT Filed: Apr. 15, 2024
(86) PCT No.: PCT/EP2024/060143

§ 371 Date: Oct. 9, 2025

(30) Foreign Application Priority Data
Apr. 26, 2023 (IT) 102023000008088
Aug. 8, 2023 (IT) 102023000016986

(51) Int. Cl. G01R 1/067; G01R 1/073

(52) U.S. Cl. CPC G01R 1/06716; G01R 1/07307

(57) ABSTRACT

A probe head for the testing of electronic devices is herein disclosed having a contact probe with a body which extends along a longitudinal axis between a first and a second end which are adapted to contact respective contact pads. The body has a maximum thickness measured along a direction that is orthogonal to the longitudinal axis and a guide having at least one guide hole configured to house at least a portion of the contact probe. The contact probe includes an elastically compliant intermediate section arranged between the first and second ends. The elastically compliant intermediate section includes a reduced portion with a thickness less than the maximum thickness of the body of the contact probe.

### FIELD OF APPLICATION

The present invention relates to a probe head adapted to perform the testing of electronic devices integrated on a semiconductor wafer, for instance high-frequency devices. The following description is made with reference to this field of application with the only purpose of simplifying the exposition thereof.

### PRIOR ART

As it is well known, a probe head is essentially a device adapted to electrically contact a plurality of contact pads or pads of a microstructure, particularly an electronic device integrated on a semiconductor wafer, with corresponding channels of a testing apparatus which performs the functionality testing thereof.

The testing performed on integrated circuits is in particular useful for detecting and isolating defective circuits as early as in the production phase. Normally, probe heads are thus used for the testing of the circuits integrated on wafers before cutting and assembling them inside a chip containment package.

A probe head essentially comprises a plurality of contact probes housed in a pair of supports or guides which are substantially plate-like and parallel to each other (generally a lower guide and an upper guide are present). These plate-like supports are equipped with proper guide holes and are located at a distance from each other, so as to leave a free area or air gap for the movement and the possible deformation of the contact probes, which are normally formed by wires of special alloys with good electrical and mechanical properties.

The contact probes generally extend between a first end portion, intended to contact the pads of the device under test, and a second end portion, intended to contact a space transformer or a printed circuit board (PCB).

The correct operation of a probe head is basically linked to two parameters: the vertical movement (or overtravel or overdrive) of the contact probes and the horizontal movement (or scrub) of the contact tips of these probes on the pads during the contact with the device under test. All these features are to be carefully evaluated and calibrated in the manufacturing step of a probe head, the good electrical connection between the contact probes and the device under test should always be ensured.

It is thus particularly important to ensure a proper contact of the contact probes with the various pads during the test.

In general, the maximum overtravel of a contact probe is equal to the dimensions of the probe part projecting with respect to the lower guide, this projecting part returning into the lower guide in case of contact with the device under test due to the bending and deformation of the probe itself. The height of this projecting part is however constrained by the mechanical resistance of the probe and is normally reduced. Moreover, it should be added that the maximum value of the overtravel of the probes can only theoretically be reached, since even with much smaller overtravels problems linked to the interlocking and to the deformation of the probes occur.

In accordance with some known solutions, contact probes having a pre-deformation are manufactured, but these solutions have various drawbacks, such as for instance the difficult maintenance and the need for particular expedients for the retention of the probes, as well as interlocking problems during the test. Another problem of these known solutions is linked to the wear of the contact pads caused by the probes themselves.

Furthermore, very short probes have been manufactured in the past in order to ensure optimum performances also for high-frequency tests, where the length of the probe is a significant problem, in particular due to the self-inductance phenomenon. In this case, however, the reduced length of the body of the probes dramatically increases the rigidity of the probe itself, causing an increase in the force exerted by the respective contact tip on the various pads, which can lead to a breaking of the pads, with irreparable damage of the device under test. The increase in the rigidity of the contact probe due to the reduction in the length of the body thereof also increases the risk of breaking the probes themselves. In this case too, there is thus the need for contact probes which are able to ensure an improved contact during the test.

The technical problem of the present invention is to devise a probe head having such structural and functional features as to allow the limitations and the drawbacks still affecting the known solutions to be overcome, in particular comprising contact probes with elastic properties such as to ensure an optimum contact with the contact pads during the test.

### SUMMARY OF THE INVENTION

The solution idea underlying the present invention is to create a probe head in which the contact probes are subjected, during the test, to an elastic deformation preferably occurring mainly (but not necessarily) in the longitudinal direction. In particular, the contact probes have at least one elastically compliant (yielding) intermediate section, so that they substantially act as an elastic spring, wherein the above elastically compliant intermediate section has a thickness that is lower than the rest of the probe body, thus reducing the overall rigidity of the contact probe.

Based on this solution idea, the above technical problem is solved by a probe head for the testing of electronic devices, comprising at least one contact probe including a body which extends along a longitudinal axis between a first end and a second end, said ends being adapted to contact respective contact pads, said body having a maximum thickness measured along a direction that is orthogonal to said longitudinal axis, and at least one guide comprising at least one guide hole configured for housing at least a portion of the contact probe, wherein the contact probe comprises at least one intermediate section arranged between the first end and the second end which is elastically compliant (yielding), and wherein the elastically compliant intermediate section comprises at least one reduced portion with a thickness that is lower than the maximum thickness of the body of the contact probe.

More particularly, the invention comprises the following additional and optional features, taken individually or in case in combination.

According to an aspect of the present invention, the entire elastically compliant intermediate section may have a thickness that is lower than the maximum thickness of the body of the contact probe.

According to an aspect of the present invention, the thickness of the reduced portion of the elastically compliant intermediate section may be overall in a range from 5 μm to 195 μm, whereas the maximum thickness of the body of the contact probe may be in a range from 10 μm to 200 μm.

According to an aspect of the present invention, the elastically compliant intermediate section may be a single section between the first end and the second end, said single section being obtained by removing material from at least one side of the body of the contact probe.

According to an aspect of the present invention, the elastically compliant intermediate section may be divided into a plurality of elastically compliant intermediate sections, each having at least one reduced portion with a thickness that is lower than the maximum thickness of the body of the contact probe. In any case, in this embodiment, the sum of the thicknesses of the reduced portions of the single elastically compliant intermediate sections is less than the maximum thickness of the body of the contact probe, said elastically compliant intermediate sections being in the form of arms that are separated from each other by respective openings which extend along the longitudinal axis of the contact probe.

According to an aspect of the present invention, the contact probe may comprise two elastically compliant intermediate sections that are separated from each other by a single opening.

According to an aspect of the present invention, the thickness of each of the reduced portions of said two elastically compliant intermediate sections may be in a range between 5 μm and 100 μm.

According to an aspect of the present invention, the contact probe may comprise a first elastically compliant intermediate section, a second elastically compliant intermediate section, and a third elastically compliant intermediate section.

According to an aspect of the present invention, the first elastically compliant intermediate section may be separated from the second elastically compliant intermediate section by a first opening, and the second elastically compliant intermediate section may be separated from the third elastically compliant intermediate section by a second opening.

According to an aspect of the present invention, the thickness of each of the reduced portions of the first, second and third elastically compliant intermediate section may be in a range between 5 μm and 95 μm.

According to an aspect of the present invention, the entire elastically compliant intermediate sections may have a thickness that is lower than the maximum thickness of the body of the contact probe.

According to an aspect of the present invention, the contact probe may have a length that is lower than 2000 μm, preferably lower than 1000 μm, even more preferably equal to or lower than 800 μm, said length being measured along the longitudinal axis of the contact probe.

According to an aspect of the present invention, the elastically compliant intermediate section may extend along the longitudinal axis by a length of 80 μm to 1000 μm and with a pitch of 100 μm to 5 μm.

According to an aspect of the present invention, the elastically compliant intermediate section may be arranged at the guide, so as to be at least partially housed in the guide hole.

According to an aspect of the present invention, the probe head may comprise a lower guide and an upper guide separated from each other by a gap, said lower guide and said upper guide comprising respective lower guide holes and upper guide holes for housing the contact probes.

According to an aspect of the present invention, the elastically compliant intermediate section may be arranged at the gap between the lower guide and the upper guide.

According to an aspect of the present invention, the contact probe may comprise stop means formed on the body thereof and configured to mechanically contact at least a portion of the guide, so as to ensure the retention of said contact probe inside the probe head.

According to an aspect of the present invention, the stop means may comprise a stopper having a transversal extension such as to define at least one shoulder configured to abut onto a face of the guide, said face being opposite a face of the guide facing toward the device under test, and/or wherein the stop means comprise at least one clip configured to mechanically interfere with the guide hole and to contact a corresponding wall of said guide hole, said clip projecting from the body of the contact probe and being configured to elastically deform during the contact with the wall of the guide hole, thereby ensuring the retention of the contact probe by mechanical interference with said guide hole.

According to an aspect of the present invention, the elastically compliant intermediate section may be embedded in a polymeric material.

According to an aspect of the present invention, the elastically compliant intermediate section may be configured to define an intensity and/or a direction of a contact force exerted by the contact probe onto the contact pads, said contact probe acting as a spring.

According to an aspect of the present invention, the elastically compliant intermediate section may be configured in such a way that the contact force exerted by the contact probe onto the contact pads is substantially directed along the longitudinal axis, with a substantially null transversal component.

According to an aspect of the present invention, the above mentioned contact force may also have a component along an axis that is different from said longitudinal axis, for example a transversal axis.

According to an aspect of the present invention, the contact probe may have a rectangular section.

According to an aspect of the present invention, the thickness of the reduced portion may be less than the maximum thickness when it is measured along one of the smaller sides of said rectangular section.

The features and advantages of the probe head according to the invention will be apparent from the following description of an exemplary embodiment thereof given by way of non-limiting example with reference to the attached drawings.

### BRIEF DESCRIPTION OF THE DRAWINGS

In the Drawings:

FIG. 1 schematically shows a probe head wherein a contact probe thereof comprises an elastically compliant intermediate section;

FIG. 2 schematically shows a contact probe of the probe head according to the present invention, in particular a side view thereof;

FIG. 3 schematically shows a contact probe of the probe head according to an embodiment of the present invention, in particular a side view thereof;

FIG. 4 schematically shows a contact probe of the probe head according to an embodiment of the present invention, in particular a side view thereof;

FIG. 5 shows a probe head according to an embodiment of the present invention;

FIGS. 6 to 9bis schematically show probe heads with contact probes according to different embodiments of the present invention, in particular with different geometries;

FIG. 10 schematically shows a probe head according to an embodiment of the present invention wherein the contact probe comprises stop means in the form of a stopper;

FIG. 11 schematically shows a probe head according to an embodiment of the present invention wherein the contact probe comprises stop means in the form of clips;

FIG. 12 Shows a Combination of the Embodiments of FIGS. 10 and 11; and

FIG. 13 schematically shows a probe head according to an embodiment wherein the elastically compliant intermediate section is embedded in a polymeric material.

### DETAILED DESCRIPTION

With the reference to the figures, a probe head for the testing of electronic devices manufactured according to the present invention is globally and schematically indicated with 100.

It should be noted that the figures are schematic views and are not drawn to scale, but they are instead drawn, so as to emphasize the important features of the invention. Furthermore, in the figures, the different elements are schematically represented, and their shape can vary depending on the desired application. Moreover, it should be noted that, in the figures, identical reference numbers refer to elements which are identical in shape or function. Finally, particular expedients described in relation to an embodiment illustrated in a figure can also be used for the other embodiments illustrated in the other figures.

Moreover, it is noted that, unless expressly stated, described process steps can also be reversed if necessary.

The probe head 100 is adapted to connect (directly or more preferably indirectly by means of a space transformer and/or a PCB) with an equipment (not illustrated in the figures) to perform the testing of electronic devices integrated on a semiconductor wafer 20, for instance (but not necessarily) high-frequency devices.

It is noted that, in the context of the present invention, the term “probe head” is used to indicate a test device without being limited by the presence or absence of particular components in addition to what is defined by the attached claims. In general, this term thus indicates a set of components which can be associated with further components for checking devices integrated on the above semiconductor wafer 20, and thus it generally indicates a system for measuring electronic devices.

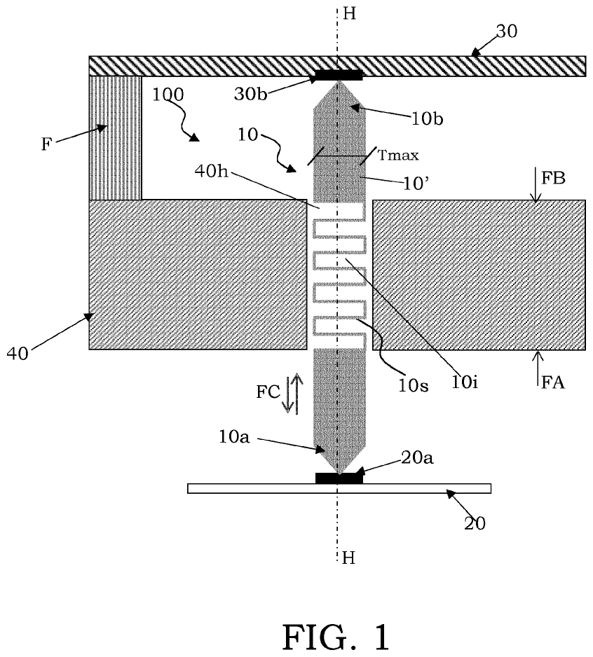

With the reference to the sectional view of FIG. 1 (which is substantially the section of a frontal view), the probe head 100 first of all comprises a plurality of contact probes 10 intended to electrically contact the devices under test integrated in the semiconductor wafer 20 with the testing apparatus.

In order to house the contact probes 10, the probe head 100 comprises at least one guide 40 equipped with guide holes 40h inside which said contact probes 10 are housed. The guide 40 thus allows, together with the guide holes 40h thereof, to house, in particular to slidingly house, at least one portion of the contact probes 10.

Each contact probe 10 comprises a probe body 10′ extending along a longitudinal axis (indicated with reference H-H) between a first end 10a and a second end 10b, which ends are adapted to contact respective pads or contact pads. By way of example, the first end 10a (also called contact tip and indicated in the field with the term “plunger”) is adapted to contact pads 20a of the device under test integrated on the semiconductor wafer 20, whereas the second and opposite end 10b (also called contact head) is adapted to contact pads 30b of a space transformer or of a printed circuit board (PCB) which can be associated with the probe head 100, said component being generically identified with reference number 30 and being generically defined as “interface board”. In general, the term “end” thus means the terminal portions of the contact probe 10, said terminal portions comprising the contact points of the probe with the pads.

In an embodiment (as illustrated by simple way of example), the pads 30b are the pads of a PCB board, even if the use of an interposer arranged between the PCB and the contact heads of the probes is obviously not excluded.

Clearly, although the ends 10a and 10b in the attached figures end with a pointed shape, they are not limited thereto and can have any shape which is suited to the needs and/or circumstances.

Moreover, it is noted that, although the figures for simplicity show a single contact probe 10, the probe head 100 can comprise any number of contact probes, depending on the various applications.

In the embodiment of FIG. 1, a frame F acting as a structural support for the probe head 100 as a whole is also provided, in particular arranged between the guide 40 and the PCB 30, this frame F being omitted in the following figures only for simplicity of illustration.

Suitably, in order to enable high-frequency tests with high performances, the contact probe 10 has a reduced length, which is in particular lower than 2000 μm, preferably lower than 1000 μm, still more preferably equal to or lower than 800 μm, said length being measured along the longitudinal axis H-H of the probe. The self-inductance phenomenon is thereby suitably reduced and an effective testing also at very high frequencies, even in the radiofrequency domain, is ensured.

In order to ensure a proper contact with the pads 20a and 30b, in particular in order to ensure a proper control of the contact force, the contact probe 10 comprises at least one intermediate section 10s arranged between the first end 10a and the second end 10b which is elastically compliant (or yielding) at least along the longitudinal axis H-H.

The elastically compliant intermediate section 10s (also indicated below as “elastic section” of the probe) is configured to define the contact force FC (in particular the direction and/or intensity thereof) exerted by the contact probe 10 on the pads 20a and/or 30b, i.e. said contact force FC can be controlled due to the structure (shape/size) of said elastically compliant intermediate section 10s, and the probe substantially acts as an elastic spring.

In particular, in a preferred embodiment, the elastically compliant intermediate section 10s is suitably configured so that the contact probe 10 exerts, onto the contact pads 20a and 30b, a contact force FC substantially directed along the longitudinal axis H-H, even if in other embodiments there can be forces also with other components, for instance such as to also generate a scrub movement: in fact configurations in which the elastically compliant intermediate section 10s is configured to generate a torsion on the pad, or a transversal scrub, are possible; in fact some embodiments can provide elastically weaker portions and elastically stronger portions of the elastically compliant intermediate section 10s, as well as helical, not necessarily symmetrical shapes for said elastically compliant intermediate section 10s.

The presence of a contact force FC mainly in the longitudinal direction reduces the risks of interlocking of the contact probe 10, even if, as above described, embodiments with various force components are not excluded. However, as above mentioned, according to other embodiments of the present invention, the contact force FC can also have a transversal component, i.e. the elastically compliant intermediate section 10s can be configured so that the contact force FC exerted by the contact probe 10 onto the contact pads has both a longitudinal/axial component and a transversal component, causing for instance a scrub of the contact tips.

For instance, in an embodiment of the present invention, the elastically compliant intermediate section 10s can comprise a wall that is elastically weaker than an opposite wall thereof, thereby causing a lateral movement during the overtravel.

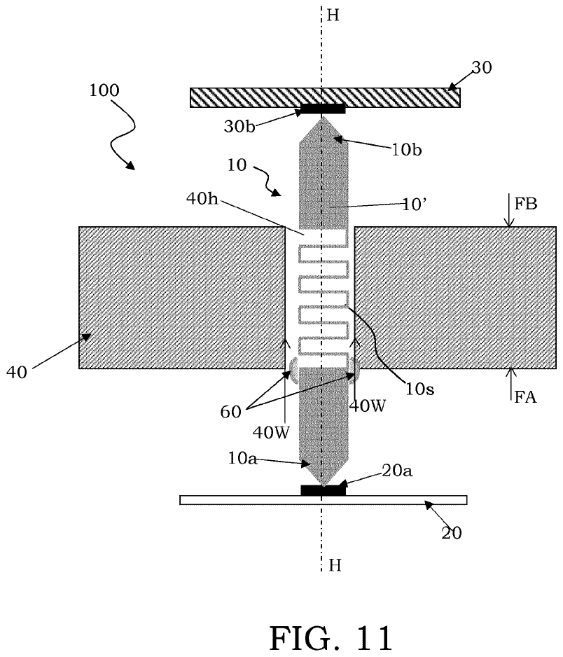

According to an embodiment of the present invention, the elastically compliant intermediate section 10s can comprise an elastic deformation mechanism (also called further elastic element, as it will be described hereafter in relation to FIG. 11) comprising arms having a different elasticity (in which for instance an arm can be elastically weaker than the other one), so that the elastic deformation of said section not only occurs in the longitudinal direction but also along other directions, for instance causing a scrub movement of the first end of the contact probe on the pads of the device under test.

According to an aspect of the present invention, the elastically compliant intermediate section 10s can also be configured to perform a torsion during the contact with the device under test and thus during the overtravel.

In a non-limiting example of the present invention, the elastically compliant intermediate section 10s can be obtained by interdigitated engravings or notches 10i formed in the body 10′ of the contact probe 10, said interdigitated engravings or notches 10i being configured so that the contact probe 10 substantially acts as an elastic spring. The substantially spring-shaped elastically compliant intermediate section 10s can thus be formed for instance by removing some material, wherein the above notches 10i are made symmetrically with respect to the longitudinal axis H-H of the contact probe 10 (even if this is not strictly necessary and asymmetrical shapes with respect to said axis can be provided).

In general, the present invention is not limited by the particular method for manufacturing the contact probe 10, what matters is the presence of the above elastic section comprising a plurality of turns which follow each other along the longitudinal axis H-H, where the term “turn” indicates in the present description the single elastic element (or elastic sub-portion) of the spring which is repeated along said longitudinal axis H-H, thereby forming a given elastic pattern, without being limited by a particular shape (for instance it does not necessarily display a cross-sectional circular profile as in a spiral spring, even if such a configuration is obviously possible), as it will be detailed hereafter.

The intermediate section 10s is thus elastically compliant in a mainly longitudinal direction (but in other configurations other directions for the deformation of the elastic section and thus for the contact force FC can also be provided, as mentioned above), so as to get compressed along said direction during the testing of the device under test. In particular, the elastically compliant intermediate section 10s allows the contact probe 10 to shorten along the longitudinal direction thereof during the normal operation of the probe head 100, with a “spring effect” which ensures a proper contact force during the overdrive, and which also allows the contact probe 10 to come back to the original dimensions thereof once said probe head 100 has been spaced apart from the device under test.

Preferably, the contact probe 10 has a non-circular cross section; in a preferred embodiment, the contact probe 10 has a rectangular section, for instance with one side having a length of 30 μm and the other side of the rectangle having a length of 70 μm (and thus in general with a major side and a minor side), even if obviously other dimensions can be provided.

Furthermore, it is noted that the contact probe 10 can be made of a composite material, such as for instance layers of Pd, PdCo, Ni, NiCo, Au, Pt, Ag, Rh, and the like, without, however, being limited by the particular material used or by the manufacturing method. In general, selections of various materials or combinations of materials (such as for instance the above-described materials or combinations thereof) are possible depending on the needs and/or circumstances.

Moreover, the body 10′ of the contact probe 10 has a maximum thickness herein indicated as “Tmax”, said thickness being measured along a direction that is orthogonal (transversal) to the longitudinal axis H-H of the contact probe 10.

The elastically compliant intermediate section 10s extends along the longitudinal axis H-H of the contact probe 10 by a length of 1000 μm to 80 μm (preferably of about 200 μm), and with a pitch (i.e. a distance at rest between the centres of two adjacent turns) of 100 μm to 5 μm.

The configuration herein illustrated ensures an optimal contact with the pads of the device under test and/or of the interface board, thanks to the elastic properties of the contact probe 10, which is a very short microprobe apt to perform tests at very high frequencies.

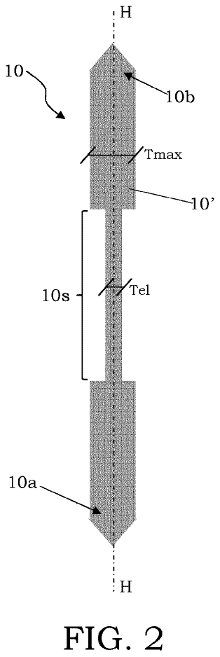

With reference now to FIG. 2 (which shows a side view of the contact probe 10) advantageously according to the present invention, in order to further reduce the rigidity of the contact probe 10, the elastically compliant intermediate section 10s comprises at least one reduced portion having a thickness (indicated with reference “Te1”) that is lower than the maximum thickness Tmax of the body 10′ thereof.

As mentioned before, the elastically compliant intermediate section 10s is structured as a plurality of elastic elements (or elastic sub-portions) which are repeated at least along the longitudinal axis H-H of the contact probe, thereby forming a given elastic pattern, without being limited by a particular shape, wherein the probe portion having the lower thickness Te1 is at said elastic pattern (in other words, the thickness reduction occurs at the elastic pattern forming the elastically compliant intermediate section 10s, which is different from the rest of the contact probe, e.g., different from the end portions).

In the embodiment illustrated in the figures, the entire elastically compliant intermediate section 10s has a thickness Te1 that is lower than the maximum thickness Tmax of the body 10′ of the contact probe 10. In other words, in this embodiment, the reduced portion of the contact probe 10 coincides with the entire elastically compliant intermediate section 10s.

It is noted that, in the shown embodiment (and considering a contact probe 10 having rectangular cross section in which there is a pair of major sides and a pair of minor sides), the thickness of the probe body 10′ is only reduced along one of the two transversal directions. In particular, the thickness of the probe body 10′, at the elastically compliant intermediate section 10s, is lower when it is measured along the minor sides of the contact probe 10 (i.e., the probe is reduced in thickness according to a side view thereof), whereas the elastically compliant intermediate section 10s is not reduced along the major sides of the contact probe (i.e., according to a frontal view thereof). However, other configurations may also be possible, in which the thickness is reduced along the major sides or along all of the sides, even if the above embodiment is preferred since it allows obtaining optimal elastic properties of the contact probe 10.

By way of example, the thickness Te1 of the reduced portion of the elastically compliant intermediate section 10s is overall comprised in a range of 5 μm to 195 μm, whereas the maximum thickness Tmax of the body 10′ of the contact probe 10 is comprised in a range of 10 μm to 200 um (obviously with a value always greater than that of thickness Te1). These values may vary based on the application and on the specific shape of the elastically compliant intermediate section 10s.

In an embodiment, as illustrated in FIG. 2, the elastically compliant intermediate section 10s is a single section arranged between the first end 10a and the second end 10b, said single section being obtained by removing material from at least one side of the body 10′ of the contact probe 10. In the embodiment illustrated in the figures, the reduced portion of the contact probe 10 is obtained by removing material symmetrically from two opposite sides of the probe body 10′.

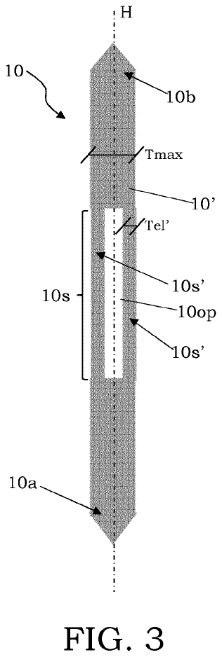

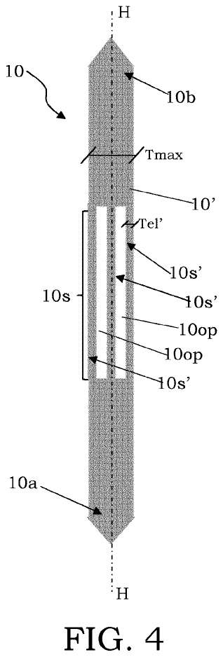

With reference now to FIGS. 3 and 4, in another embodiment of the present invention, the elastically compliant intermediate section 10s is divided into a plurality of elastically compliant intermediate sections (each indicated with reference 10s′) each having at least one reduced portion with a thickness (now indicated with reference Te1′) that is lower than the maximum thickness Tmax of the body 10′ of the contact probe 10. In this way, it is possible to form different elastic sections on independent levels.

More particularly, in the embodiment illustrated in the figures, the various elastically compliant intermediate sections 10s′ are in the form of arms separated from each other by respective openings (indicated with reference 10op) which extend along the longitudinal axis H-H of the contact probe 10.

Still more particularly, the various elastically compliant intermediate sections 10s′ are side by side along the minor side of the contact probe, even if other less preferred configurations may also be provided.

In any case, the sum of the reduced thicknesses Te1′ of all of the single elastically compliant intermediate sections 10s′ is always less than the maximum thickness Tmax of the body 10′ of the contact probe 10, thus resulting in a less effective thickness of the elastic section and in a reduction of the overall rigidity of the probe.

Even in this case, in the embodiment illustrated in the figures, the single elastically compliant intermediate sections 10s′ in their entirety have a thickness that is less than the rest of the body 10′, and thus the single reduced portions coincide with said single intermediate sections. In other words, each elastically compliant intermediate section 10s′ has, in its entirety, a thickness Te1′ that is less than the maximum thickness Tmax of the body 10′ of the contact probe 10, even if the present invention is not limited to this particular configuration.

In the embodiment of FIG. 3, the contact probe 10 comprises two elastically compliant intermediate sections 10s′ separated from each other by a single opening 10op.

In this case, the thickness Te1′ of each of the reduced portions of said two elastically compliant intermediate sections 10s′ is in a range between 5 μm and 100 μm. The value of the maximum thickness Tmax in this case is adaptable according to the value of the reduced thickness Te1′: for instance, with a thickness Te1′ equal to 100 μm a thickness Tmax equal to 200 μm (as previously seen) can be used. These values may anyway vary based on the application and on the specific shape of the elastically compliant intermediate section 10s.

Furthermore, in another embodiment illustrated in FIG. 4, the contact probe 10 comprises a first elastically compliant intermediate section, a second elastically compliant intermediate section and a third elastically compliant intermediate section, i.e. it is formed by three arms that follow one another along the minor side of the contact probe 10. The first elastically compliant intermediate section is separated from the second elastically compliant intermediate section by a first opening, and the second elastically compliant intermediate section is separated from the third elastically compliant intermediate section by a second opening.

In this case, the thickness Te1′ of each of the reduced portions of said three elastically compliant intermediate sections 10s′ is in a range between 5 μm and 95 μm. In this case, the value of the maximum thickness Tmax is adaptable based on the value of Te1′: for instance, with a thickness Te1′ equal to 95 μm, a thickness Tmax equal to 200 μm (as previously seen) can be used. Even in this case, these values may vary based on the application and on the specific shape of the elastically compliant intermediate section 10s.

A preferred embodiment has been described so far, in which a single guide 40 is provided (for instance having an overall thickness which is equal to 320 μm, even if other thicknesses are obviously possible, for instance higher thicknesses, thus allowing extending the elastic section of the contact probe) and in which the elastically compliant intermediate section 10s is positioned at the guide 40, so as to be at least partially housed in the guide hole 40h, substantially in an intermediate position. In other words, an embodiment which provides for the presence of a single intermediate guide 40 which houses the elastic section of the contact probe 10 has been described so far. This embodiment has a greater simplicity of assembly and lower production costs.

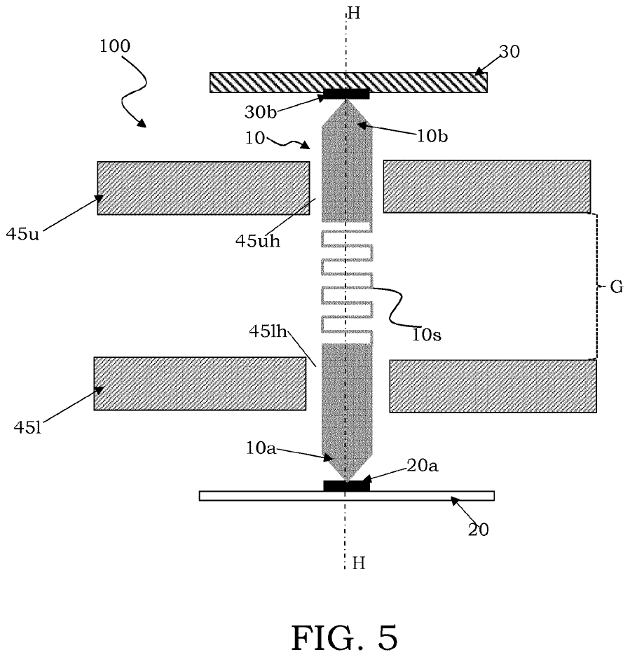

Alternatively, with reference to FIG. 5, the probe head 100 can comprise a lower guide 45l and an upper guide 45u separated from each other by an air gap or gap G, at which the elastically compliant intermediate section 10s lies, thus with the possibility of increasing the extension of this elastic section. The lower guide 45l and the upper guide 45u comprise respective lower guide holes 45lh and upper guide holes 45uh for housing the contact probes 10.

In an embodiment (not illustrated in the figures), the lower guide holes 45lh and the upper guide holes 45uh can possibly be unaligned (shifted) with respect to each other, i.e., with reference to a single probe, the centres thereof do not lie on a same longitudinal axis, thereby creating a slight deformation of the contact probe 10 to favour the retention and the possible contact thereof with the walls of the holes.

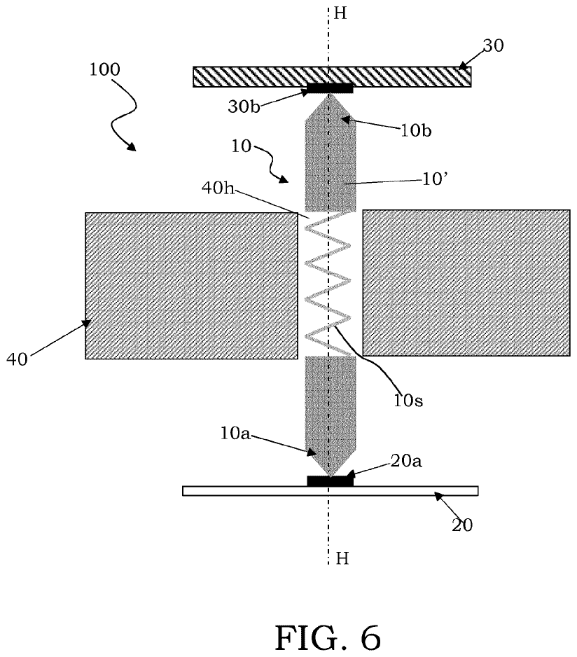

Referring now to FIGS. 6 to 12, various shapes are possible for the elastically compliant intermediate section 10s, in addition to the standard shape represented in FIGS. 1 to 4, wherein the elastic section is formed by elastic elements which appear as steps in the sectional views shown. In these various shapes, single elastic elements (being different from one shape to another one) are defined, which are repeated along the longitudinal axis H-H, so as to define different elastic patterns, which different mechanical properties of the contact probe 10 correspond to.

In the case of a contact probe 10 provided with various elastic sections 10s′, each of them may have one of the shapes herein described.

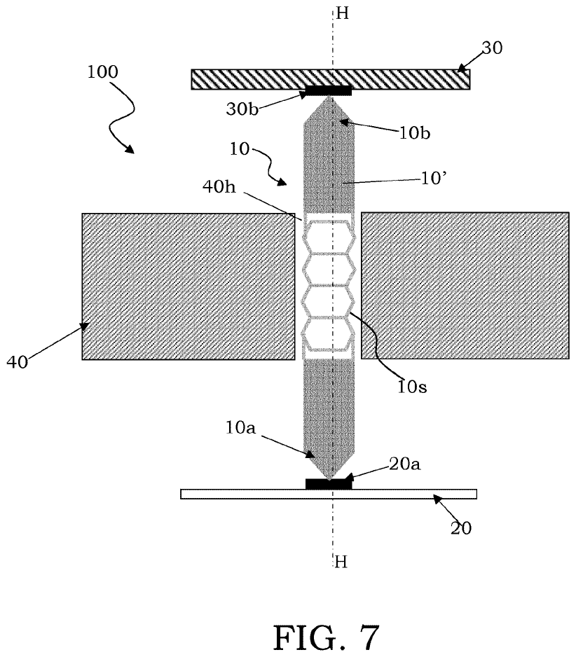

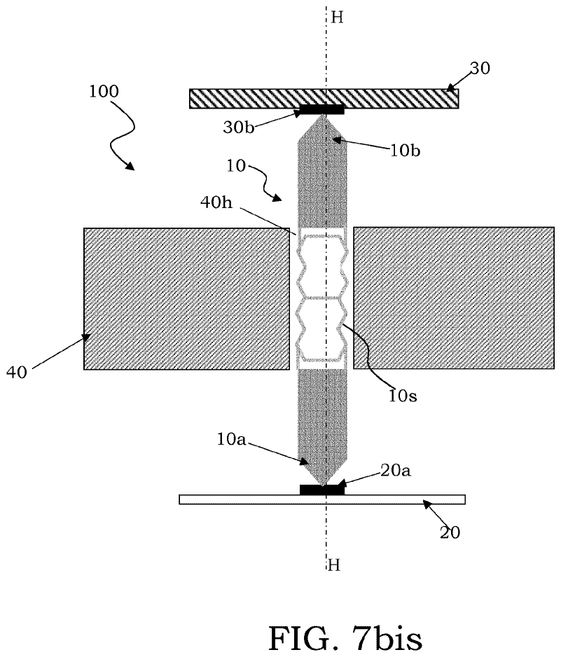

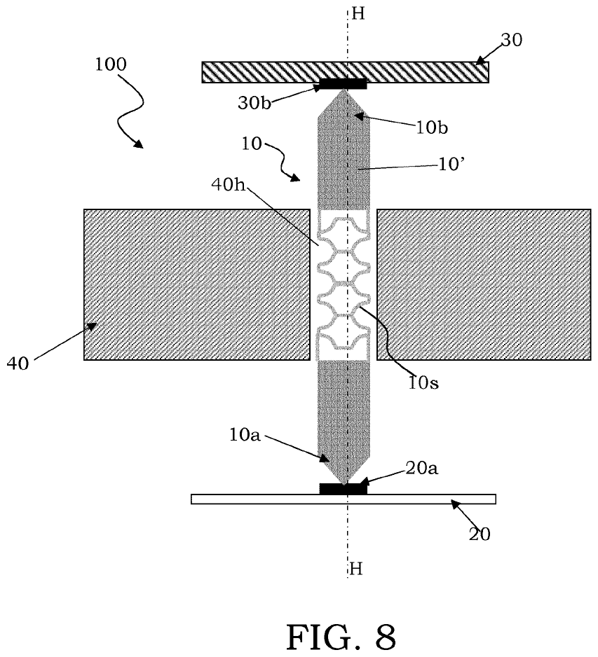

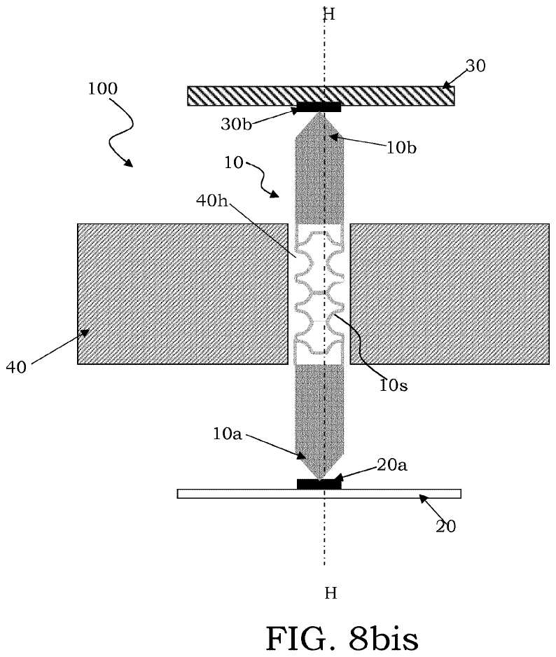

For instance, among the various possible geometries, the elastically compliant intermediate section 10s can have a shape with a sawtooth development (FIG. 6), or a spiral shape, or it can even be structured as a plurality elastic elements having, in a longitudinal section, the shape of polygonal elements connected to each other and which follow each other, such as for instance a succession of interconnected hexagons (FIGS. 7 and 8). Said polygonal elements can have a closed profile (i.e. they can have areas not communicating with each other), even if this is not necessary and embodiments in which the various connected polygonal elements have areas communicating with each other, even only for a short section, can be provided.

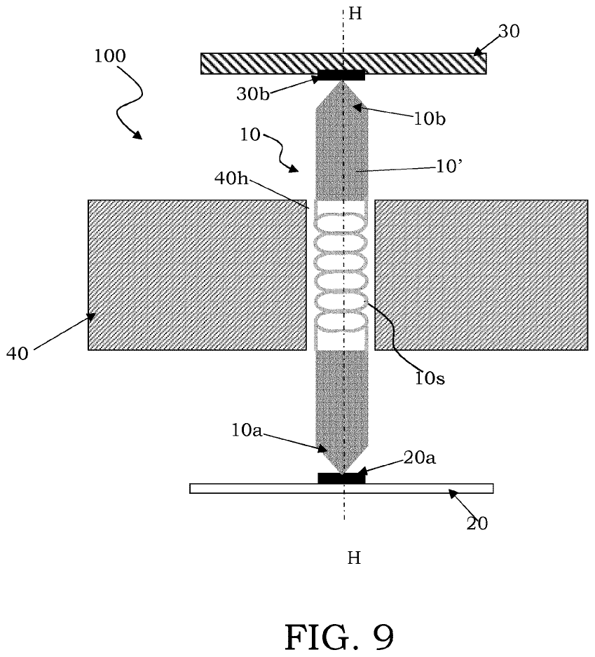

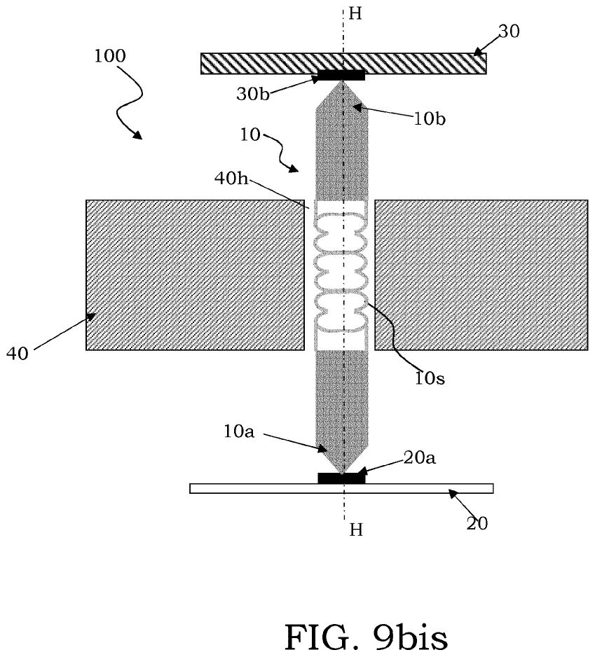

Alternatively, the elastically compliant intermediate section 10s can be structured as a plurality of elastic elements, each having the shape of interconnected elements with an oblong profile (oval for instance) and which follow each other along the longitudinal axis H-H (FIG. 9), each one of said elements with the oblong profile developing along an axis of symmetry which is substantially orthogonal to the longitudinal axis H-H of the contact probe 10 and being slightly squashed in the centre thereof.

More particularly, with reference to the above-described geometries, the embodiment of FIG. 6 allows the overdrive of the contact probe 10 to be increased, the embodiment of FIG. 7 helps to keep the contact probe 10 in a straight configuration, but at the same time it increases the strength and rigidity thereof, while the embodiment of FIG. 8, in which the slanted sides of the hexagon are replaced by curvilinear sections, helps to keep the contact probe 10 in a straight configuration as in FIG. 7 but at the same time it increases the flexibility and reduces the strength thereof. The embodiment of FIG. 9 simulates the effect of two joined standard springs, with the purpose of increasing the symmetry and keeping a good flexibility of the contact probe 10.

Furthermore, the variants shown in FIG. 7bis, 8bis, and 9bis correspond to the geometries of FIGS. 7, 8, and 9 respectively, except that the single elastic elements of said previous figures are now grouped in interconnected pairs, each pair being defined by a single closed or half-closed profile, with the purpose of further reducing the rigidity of the elastic section and thus of the contact probe 10 as a whole.

Obviously, the illustrated embodiments are only indicative and do not limit the scope of the present invention, while the various embodiments can be varied depending on the applications, or in some cases they can also combined with each other (and in some cases it is also possible to use single elastically compliant intermediate sections 10s′ with different shapes from each other).

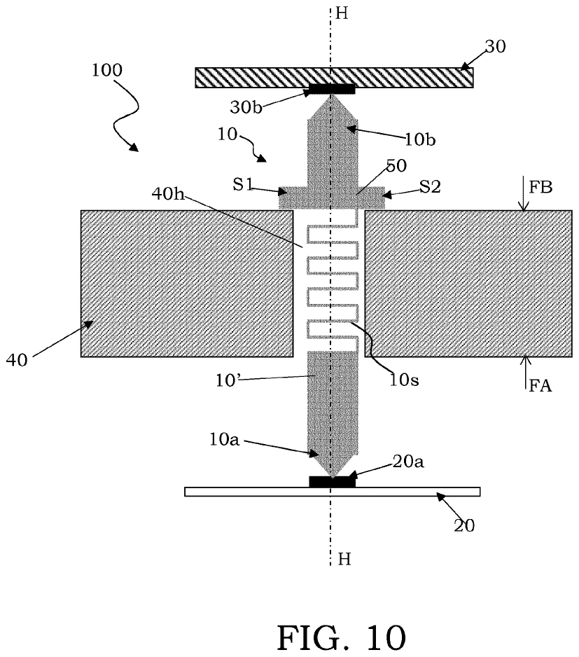

Referring now to FIG. 10, in an embodiment of the present invention, the contact probe 10 also comprises stop means formed on the body 10′ thereof and configured to mechanically contact at least one portion of the guide 40, so as to cause the retention of the probe inside the probe head 100.

The position of the contact probe 10 inside the probe head 100 can be thereby fixed, preventing it from slipping outside the guide hole 40h.

In the particular example of FIG. 10, the stop means are shaped as a stopper (indicated with the reference 50) having a transversal extension such as to define at least one shoulder (reference S1 or S2) configured to abut onto an upper face FB of the guide 40, i.e. abutting onto a face opposite a face FA facing towards the device under test (and thus having at least one abutting surface). The stopper 50 is thus protruding from at least one wall of the contact probe 10 (as a whole, the stopper 50 joined to the probe body portion can have a transversal extension which is greater than the one of the guide holes for a suitable retention of the contact probe).

In particular, in a preferred embodiment, the stopper 50 comprises two shoulders S1 and S2, which are symmetrical with respect to the longitudinal axis H-H of the contact probe 10, defining two surfaces for abutting onto the face FB of the guide 40. In any case, it is noted once again that the figures are only applicative examples of the present invention and other configurations for the stopper can obviously be adopted (for instance the stopper can protrude from a single wall of the contact probe 10 and not from two opposite walls as depicted, as well as it can have any suitable configuration).

In addition or as an alternative, in an embodiment of the present invention represented in FIG. 11, the stop means of the probe comprise at least one clip 60 configured to mechanically interfere with the guide hole 40h and thereby to contact a wall 40W of said guide hole 40h. More particularly, the clip 60 projects from the body 10′ of the contact probe 10 and is configured to elastically deform during the contact with the wall 40W of the guide hole 40h, thereby causing the retention of the contact probe 10 by mechanical interference with said guide hole 40h.

In the example of the figures, the clip 60 is formed at the face FA of the guide 40, i.e. at the lower face facing towards the device under test DUT.

Due to the presence of the stopper 50 and/or of the clips 60, the contact probe 10 is thereby prevented from exiting the guide hole 40h when there is not the device under test and/or the PCB (and thus when in the latter case, when the probe head 100 is overturned), thus simplifying the management of the probe head 100.

In the preferred embodiment, there are two clips 60 arranged on the body 10′ symmetrically with respect to the longitudinal axis H-H, these clips 60 being adapted to contact respective walls 40W of the guide hole 40h, ensuring a mobile interlocking of the contact probe 10.

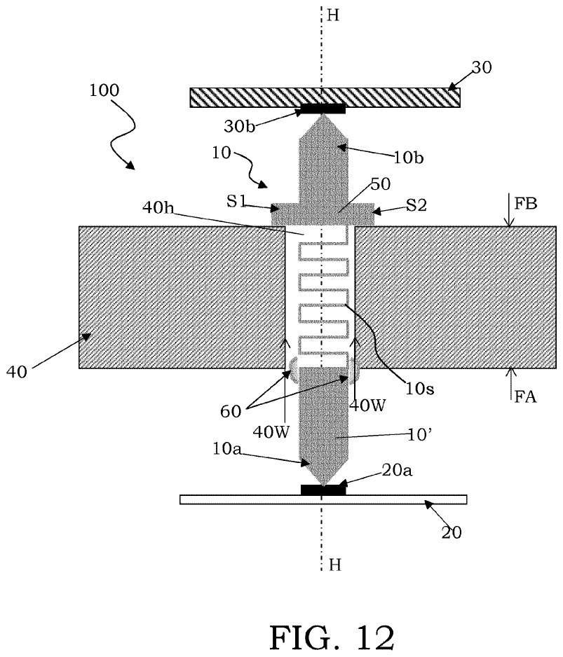

Obviously, a combination of the stopper 50 and the clips 60 can also be provided, as indicated in the example of FIG. 12.

In general, it is preferable that the clip 60 has a rigidity which is lower than the one of the elastically compliant intermediate section 10s, so as to avoid a deformation of the contact probe 10 during the assembly and ensure however a proper handling of the contact probe 10 along the longitudinal axis H-H during the test.

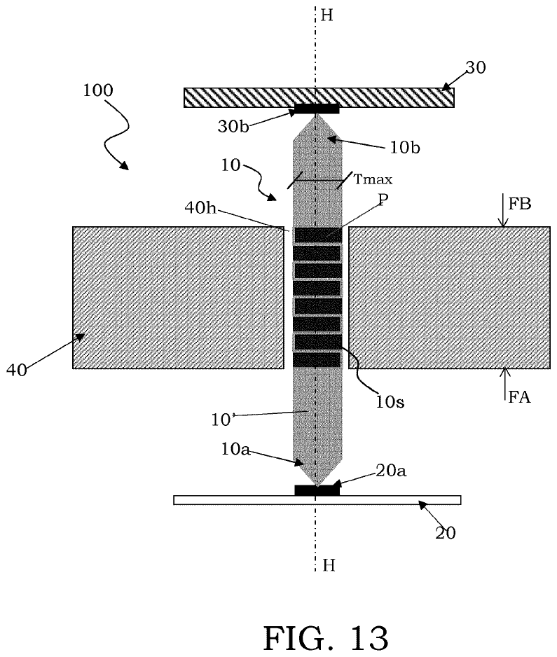

Referring now to the embodiment of FIG. 13, the elastically compliant intermediate section 10s may be at least partially embedded in a polymeric material (identified herein with the reference P), which ensures a better mechanical stability of the contact probe 10 as a whole. For instance, the elastically compliant intermediate section 10s can be completely embedded in the polymeric material P, and thus in this case this material can completely extend in the guide hole 40h.

In an embodiment, the polymeric material P is polyamide or is selected from other materials which are similar to polyamide materials, even if the present invention is not limited in any way by the polymeric coating material used, since any suitable material can be selected based on the requirements.

In this case, the presence of the polymeric material P allows to increase the elastic response of the elastically compliant intermediate section 10s itself and to ensure a greater strength to lateral deformation.

Obviously, this embodiment can be combined with the other ones, such as for instance with the presence of the stop means, as well as with any one of the herein-described geometries, or with any one of the configurations of the guide.

Summarizing the above, in conclusion, the present invention allows to successfully overcome the technical problem, providing the above probe head (which comprises very short contact probes acting as elastic springs) and solving all the drawbacks of the prior art in a simple way.

It is possible in this way to effectively control the intensity of the contact force and more generally the compression of the contact probes, by suitably shaping and sizing the elastically compliant intermediate section.

Advantageously according to the present invention, the thickness of the elastic section of the probe is reduced to further reduce the rigidity thereof.

It is also possible to form the elastic section on multiple levels independent of each other, separated by longitudinal slots or openings, still maintaining an overall reduced thickness of said elastic section.

In general, an elastic section with very reduced rigidity is obtained.

The reduced length of the contact probes, which can thus be seen as micro-springs, makes the probe head of the present invention suited to test high-frequency devices, while solving at the same time the problem of the rigidity of the short probes of the known solutions.

Furthermore, the probe head according to the invention, thanks to its advantageous shape, allows a very limited consumption of the contact pads.

Different geometries can be envisaged for the elastic section, as well as different directions and types of deformation, not necessarily exclusively longitudinal. The above-described particular configurations allow to ensure a proper stability of the contact probes and to avoid a deformation thereof during the test, as well as they allow the proper retention thereof and a simple assembly.

Finally, it is noted that all the above embodiments can be combined with each other, even when said combination is not expressly illustrated or described. Although most figures show, not to burden the description, an elastically compliant intermediate section with a step-like section, all the various embodiments of the present invention can also be applied to the other described geometries (possibly also combinable with each other); for this reason, the configuration with reduced thickness can be applied to all possible designs for the the elastic section.

Obviously, in order to meet contingent and specific requirements, a person skilled in the art can bring to the above-described probe head several modifications and variants, all falling within the scope of protection of the invention as defined by the following claims.

1. A probe head for testing electronic devices, comprising:
at least one contact probe comprising a body which extends along a longitudinal axis between a first end and a second end, said ends being adapted to contact respective contact pads, said body having a maximum thickness measured along a direction orthogonal to said longitudinal axis; and
at least one guide comprising at least one guide hole configured to house at least a portion of the contact probe,
wherein the contact probe comprises at least one intermediate section arranged between the first end and the second end, said intermediate section being elastically compliant, and
wherein the elastically compliant intermediate section comprises at least one reduced portion having a thickness that is less than the maximum thickness of the body of the contact probe.

2. The probe head according to claim 1, wherein the entire elastically compliant intermediate section has a thickness that is less than the maximum thickness of the body of the contact probe.

3. The probe head according to claim 1, wherein the thickness of the reduced portion of the elastically compliant intermediate section is overall in a range from 5 μm to 195 μm, and the maximum thickness of the body of the contact probe is in a range from 10 μm to 200 μm.

4. The probe head according to claim 1, wherein the elastically compliant intermediate section is a single section between the first end and the second end, said single section being obtained by removing material from at least one side of the body of the contact probe.

5. The probe head according to claim 1, wherein the elastically compliant intermediate section is divided into a plurality of elastically compliant intermediate sections each having at least one reduced portion with a thickness (Te1′) that is less than the maximum thickness of the body of the contact probe, the sum of the thicknesses of all said reduced portions of the single elastically compliant intermediate sections being less than the maximum thickness of the body of the contact probe, said elastically compliant intermediate sections being in the form of arms that are separated from each other by respective openings which extend along the longitudinal axis of the contact probe.

6. The probe head according to claim 5, wherein the contact probe comprises two elastically compliant intermediate sections separated from each other by a single opening.

7. The probe head according to claim 6, wherein the thickness of each of the reduced portions of said two elastically compliant intermediate sections is in a range between 5 μm and 100 μm.

8. The probe head according to claim 5, wherein the contact probe comprises a first elastically compliant intermediate section, a second elastically compliant intermediate section, and a third elastically compliant intermediate section, wherein the first elastically compliant intermediate section is separated from the second elastically compliant intermediate section by a first opening, and wherein said second elastically compliant intermediate section is separated from the third elastically compliant intermediate section by a second opening.

9. The probe head according to claim 8, wherein the thickness of each of the reduced portions of said first, second and third elastically compliant intermediate section is in a range between 5 μm and 95 μm.

10. The probe head according to claim 5, wherein the entire elastically compliant intermediate sections have a thickness that is lower less than the maximum thickness of the body of the contact probe.

11. The probe head according to claim 1, wherein the contact probe has a length less than 2000 μm, said length being measured along the longitudinal axis.

12. The probe head according to claim 1, wherein the elastically compliant intermediate section extends along the longitudinal axis by a length from 80 μm to 1000 μm, and with a pitch from 5 μm to 100 μm.

13. The probe head according claim 1, wherein the elastically compliant intermediate section is arranged at the guide, so as to be at least partially housed in the guide hole.

14. The probe head according to claim 1, comprising a lower guide and an upper guide separated from each other by a gap, said lower guide and said upper guide comprising respective lower guide holes and upper guide holes for housing the contact probes.

15. The probe head according to claim 14, wherein the elastically compliant intermediate section is arranged at the gap between the lower guide and the upper guide.

16. The probe head according to claim 1, wherein the contact probe comprises stop means formed on the body thereof and configured to mechanically contact at least a portion of the guide, so as to cause the retention of said contact probe inside the measuring head.

17. The probe head according to claim 16, wherein the stop means comprise a stopper having a transversal extension such as to define at least one shoulder configured to abut onto a face of the guide, said face being opposite a face of the guide facing towards the device under test, and/or wherein the stop means comprise at least one clip configured to mechanically interfere with the guide hole and to contact a corresponding wall of said guide hole, said clip projecting from the body of the contact probe and being configured to elastically deform during the contact with the wall of the guide hole, thereby causing the retention of the contact probe by mechanical interference with said guide hole.

18. The probe head according claim 1, wherein the elastically compliant intermediate section is embedded in a polymeric material.

19. The probe head according to claim 1, wherein the elastically compliant intermediate section is configured to define an intensity and/or direction of a contact force exerted by the contact probe on the contact pads said contact probe acting as a spring, and wherein said elastically compliant intermediate section is configured in such a way that the contact force exerted by the contact probe on the contact pads is directed substantially along the longitudinal axis, with a substantially null transversal component, or wherein said contact force also has a component along an axis that is different from said longitudinal axis, for example transversal.

20. The probe head according to claim 1, wherein the contact probe has a rectangular section, and wherein the thickness of the reduced portion is less than the maximum thickness when it is measured along one of the minor sides of said rectangular section.
